(19) United States
(12) Patent Application Publication
(10) Pub. No.: US 2026/0349011 A1
(43) Pub. Date: Nov. 5, 2026

(54) CURRENT SENSOR SPACED APART FROM POWER LINE

(71) Applicant: EG KOREA CO.,LTD., Cheongju-si (KR)

(72) Inventors: Chul Bum JOO, Busan (KR); Bong Jun KIM, Daejeon (KR); Tae Woo KIM, Seoul (KR)

(73) Assignee: EG KOREA CO.,LTD., Cheongju-si (KR)

(21) Appl. No.: 19/705,937

(22) Filed: Jun. 12, 2026

Related U.S. Application Data
(63) Continuation of application No. PCT/KR2025/004274, filed on Apr. 1, 2025.

(30) Foreign Application Priority Data
Sep. 11, 2024 (KR) 10-2024-0124249

(51) Int. Cl. G01R 15/18; G01R 19/00

(52) U.S. Cl. CPC G01R 15/181; G01R 19/0092

(57) ABSTRACT

The present disclosure discloses a current sensor spaced apart from a power line configured to measure a current of a power transmission conductor provided in the power line that transmits power, including a sensor unit including a substrate including a plurality of conductor layers and a sensing coil outputting a sensing signal induced by magnetic coupling with magnetic flux generated by a current flowing through the power line, the sensing coil including a plurality of upper patterns and lower patterns respectively formed on a pair of conductor layers selected from the plurality of conductor layers and formed in a coil shape, in which the sensor unit is disposed on one side of the power line such that a central axis of the sensing coil intersects a current direction of the power line.

### CROSS REFERENCE TO RELATED APPLICATION

This application is a Continuation Application of International Application No. PCT/KR2025/004274, filed Apr. 1, 2025, which claims the benefit of priority under 35 U.S.C. §119 to Korean Patent Application No. 10-2024-0124249, filed on Sep. 11, 2024, disclosures of which are incorporated herein by reference in its entirety.

### TECHNICAL FIELD

The present disclosure relates to a current sensor spaced apart from a power line, and more particularly, to a current sensor spaced apart from a power line which is spaced apart from a surface of a power line or power transmission conductor so as to be suitable for measuring large currents.

### BACKGROUND ART

A current sensor is a sensor that detects current flowing through a conductor (e.g., a power transmission conductor of a power line, a busbar, etc.) to be measured. Among detection methods, magnetic field detection methods using a magnetic field around a conductor through which current flows may be broadly classified into sensors using a current transformer (CT) and sensors using a Hall element.

Since a CT element utilizes the principle of a transformer, the CT element is generally applied to the measurement of AC current that changes over time. When a current flows through a conductor, a magnetic field is formed around the conductor. In a donut-shaped CT through which the conductor passes, an induced current flows through a coil of the CT due to the magnetic field around the conductor when an AC current flows through the conductor.

The Hall element is an element using a Hall effect in which an electromotive force is generated in a direction perpendicular to both current and a magnetic field when the magnetic field is applied in the direction perpendicular to the current. The sensor using the Hall effect is referred to as a Hall sensor, and a detection signal is generated by a change in a magnetic field of a magnetic object.

However, the current detection method using the CT has a structure in which a coil is wound around a magnetic core. When the magnetizing force increases beyond a certain level, the magnetic flux density no longer increases, and the magnetic core becomes magnetically saturated, resulting in difficulty in measuring large short-circuit currents, ground fault currents, and overcurrents.

Furthermore, the Hall elements also require a magnetic core, and therefore have not only limitations related to magnetic saturation but also constraints in miniaturization. In addition, because the Hall elements are highly sensitive to magnetic signals, they are susceptible to noise; unless electromagnetic noise is sufficiently shielded, magnetic fields induced in an active state of neighboring busbars may be introduced as noise, thereby increasing measurement errors.

In addition, most magnetic field detection-type current sensors are configured such that a power line passes through an interior of a core. Accordingly, the magnetic field detection-type current sensors cannot be mounted on existing power lines by simple attachment thereto. In addition, the magnetic field detection-type current sensors have a disadvantage in that a mounting area thereof is large.

### DISCLOSURE

### Technical Problem

Therefore, the present disclosure has been devised to solve the problems of the prior art, and an object of the present disclosure provides a current sensor spaced apart from a power line suitable for measuring large currents, having a structure spaced apart from a surface of a power line or power transmission conductor.

In addition, the present disclosure provides a current sensor spaced apart from a power line, which can be easily installed and removed by being disposed in an open structure at a position spaced apart from one side of the power line.

Furthermore, the present disclosure provides a current sensor spaced apart from a power line that can minimize the influence of noise caused by an electric field from a power line and minimize a size of a sensor itself.

Objects of the present disclosure are not limited to the above-mentioned objects. That is, other objects that are not mentioned may be obviously understood by those skilled in the art to which the present disclosure pertains from the following description.

### Technical Solution

According to an aspect of the present disclosure, a current sensor spaced apart from a power line configured to measure a current of a power transmission conductor provided in the power line that transmits power includes: a sensor unit including a substrate including a plurality of conductor layers and a sensing coil outputting a sensing signal induced by magnetic coupling with magnetic flux generated by a current flowing through the power line, the sensing coil including a plurality of upper patterns and lower patterns respectively formed on a pair of conductor layers selected from the plurality of conductor layers and formed in a coil shape, in which the sensor unit is disposed on one side of the power line such that a central axis of the sensing coil intersects a current direction of the power line, and the lower pattern of the sensing coil is disposed such that the lower pattern is spaced apart from the surface of the power transmission conductor by a separation distance greater than or equal to a predetermined distance.

The sensing coil may include: a plurality of upper patterns formed parallel to each other with a first pattern spacing on an upper layer among the pair of conductor layers; a plurality of lower patterns formed parallel to each other with a second pattern spacing on a lower layer among the pair of conductor layers; and a plurality of vertical conductors formed within the substrate corresponding to each end portion of the plurality of upper patterns and lower patterns, respectively, and electrically connecting the upper and lower patterns to form a coil, and the sensing signal is induced at both end portions of the sensing coil by magnetic induction with the magnetic flux generated by the current flowing through the power transmission conductor.

The separation distance may be set to be a larger value as the current of the power transmission conductor to be measured increases.

The upper pattern of the sensing coil may be formed such that the first pattern spacing of the upper pattern positioned outward in a direction of the central axis of the sensing coil is larger than the first pattern spacing of the upper pattern positioned inward.

The lower pattern of the sensing coil may be formed such that the second pattern spacing of the lower pattern positioned outward in the direction of the central axis of the sensing coil is smaller than the second pattern spacing of the lower pattern positioned inward.

The current sensor may further include: a spacer configured to fix the sensor unit to the power line or a base panel on which the power line is disposed such that the lower pattern of the sensing coil and the surface of the power transmission conductor are disposed while maintaining the separation distance.

The spacer may be configured to form an empty space between the lower pattern of the sensing coil and the surface of the power transmission conductor.

The current sensor may further include: a sensing circuit unit configured to operate using a signal ground and power supply voltage as a power supply, receive the sensing signal from the sensor unit to detect the current flowing through the power transmission conductor, and output a control signal indicating a detection result of the current or a control command according to the detection result.

The sensing circuit unit may include: an amplifier unit configured to amplify the sensing signal; a control unit configured to receive the amplified sensing signal from the amplifier unit and output a control signal that indicates the current detection result or a control command based on the detection result; and a power supply unit configured to generate and supply the power supply voltage to the amplifier unit and the control unit.

The current sensor may further include a conductive shield unit interposed between the sensor unit and the power line to shield the electric field from the power transmission conductor toward the sensor unit.

The shield unit may be grounded to earth ground.

The shield unit may be electrically connected to a signal ground of the sensing circuit unit.

The shield unit may be grounded to earth ground by a first shield wire and electrically connected to the signal ground of the sensing circuit unit by a second shield wire.

### Advantageous Effects

The current sensor spaced apart from the power line according to the present disclosure is structured to be spaced apart from the surface of the power line or the power transmission conductor, and thus is suitable for measuring the large short-circuit current, ground fault current, or overcurrent.

In addition, according to the present disclosure, it is possible to facilitate the installation or removal of the current sensor as the current sensor is spaced apart from one side of the power line and disposed in an open structure.

In addition, according to the present disclosure, it is possible to minimize the influence of noise caused by the electric field from the power line and miniaturize the size of the sensor itself.

### BRIEF DESCRIPTION OF THE DRAWINGS

FIG. 1 is a block diagram illustrating a current sensor spaced apart from a power line according to the present disclosure.

FIG. 2 is a diagram illustrating a case where the current sensor is affected by an electric field from the power line.

FIG. 3 is a perspective view illustrating a state in which the current sensor of the present disclosure is spaced apart from the power line.

FIG. 4 is a cross-sectional view of the current sensor of the present disclosure projected in an x-axis direction.

FIG. 5 is a cross-sectional view of a current sensor according to another embodiment of the present disclosure.

FIG. 6 is a diagram illustrating a configuration that maintains a separation distance of the current sensor using a spacer.

FIG. 7 is a block diagram of the current sensor according to the present disclosure configured by adding a shield unit to block the influence of electric field of the power line.

### BEST MODE

An exemplary embodiment of the present disclosure will be described in detail with reference to the accompanying drawings. The following detailed description is merely illustrative, and merely illustrates a preferred embodiment of the present disclosure.

A current sensor spaced apart from a power line according to the present disclosure is a current sensor configured to measure a current of a power transmission conductor provided in a power line that transmits power using magnetic induction. Unlike the conventional CT current sensors that utilize a closed magnetic core, the current sensor is manufactured as an open structure without a magnetic core and is configured to be disposed parallel to the power line.

Through this configuration, the current sensor of the present disclosure is suitable for measuring large short-circuit currents, ground fault currents, or overcurrents because the current sensor does not use a magnetic core. Furthermore, since the current senor is configured as an open structure, the current sensor has the advantage of being easy to install or remove from the power line.

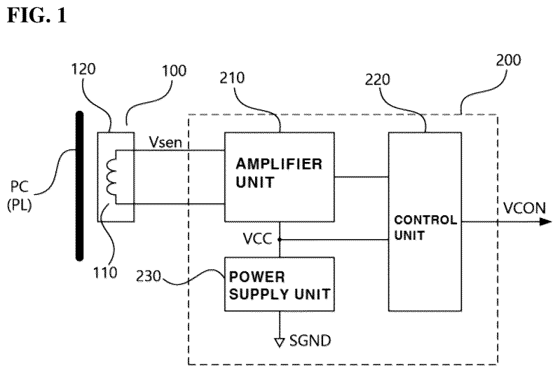

FIG. 1 is a block diagram illustrating a current sensor spaced apart from a power line according to the present disclosure.

Referring to FIG. 1, a current sensor spaced apart from a power line according to the present disclosure is a current sensor disposed parallel to a power line PL to measure a current of a power transmission conductor PC provided in the power line PL that transmits power, and includes a sensor unit 100 that includes a substrate 120 including a plurality of conductor layers and a sensing coil 110 outputting a sensing signal Vsen induced by magnetic coupling with magnetic flux generated by a current flowing through the power line PL, wherein the sensing coil 110 includes a plurality of upper patterns and lower patterns respectively formed on a pair of conductor layers selected from the plurality of conductor layers and is formed in a coil shape.

In addition, the current sensor of the present disclosure may further include a sensing circuit unit 200 configured to operate using signal ground SGND and power supply voltage VCC as a power supply, receive a magnetic-induced sensing signal Vsen from the sensor unit 100 to detect the current flowing through the power transmission conductor PC, and output a control signal VCON that indicates the current detection result or a control command based on the detection result.

The power line PL may be configured solely of the power transmission conductor PC, or may be configured to further include wire coating covering the power transmission conductor PC with an insulator. Here, the power transmission conductor PC may be a conventional circular wire or a busbar configured in a flat bar shape, or may be further configured to include a conductor capable of conducting current.

The substrate 120 may be a multilayer printed circuit board (PCB) having two or more conductor layers, but as long as the substrate has a structure in which an insulating layer (dielectric layer) and a conductor layer are stacked so that two or more conductor layers are provided, the substrate is not limited to a PCB, and may be configured as a single multilayer substrate or as a multilayer structure formed by stacking a plurality of substrates.

The sensing coil 110 is formed in a coil shape by a plurality of patterns formed on the conductor layers of the substrate 120 and vertical conductors 113 connecting the patterns, and is disposed parallel to one side of the power line PL so that a central axis of the sensing coil 110 intersects a current direction of the power line PL, thereby magnetically coupling to the magnetic flux formed around the power line PL to induce the sensing signal Vsen.

The detailed structure of the sensing coil 110 will be described below.

The sensing circuit unit 200 may be configured to receive the magnetic-induced sensing signal Vsen from the sensor unit 100, detect the current flowing through the power transmission conductor PC, and output the control signal VCON that indicates the detection result or the control command based on the detection result.

For example, the sensing circuit unit 200 may be configured to include an amplifier unit 210 that receives and amplifies the magnetic-induced sensing signal Vsen from the sensor unit 100, a control unit 220 that receives the amplified sensing signal Vsen from the amplifier unit 210 and outputs the control signal VCON that indicates the current detection result or the control command based on the detection result, and a power supply unit 230 that generates and supplies a power supply voltage VCC to the amplifier unit 210 and the control unit 220.

The amplifier unit 210 may be designed to have an appropriate amplification ratio by considering the sensing signal Vsen induced in response to the magnitude of the current to be measured, and a filter function to pass the required frequency or remove noise signals may be further added.

The control unit 220 may output the control signal VCON indicating a detection result of detecting a current value from the amplified sensing signal Vsen, or output the control signal VCON indicating the control command to control switches to cut off the current flowing through the power line PL when the current value exceeds a preset threshold value according to the detection result.

To this end, although not specifically illustrated in the drawing, the control unit 220 may be configured to include a comparator for comparing the amplified sensing signal Vsen with a threshold value, an MCU for performing digital calculations and processing, and a communication means for transmitting and receiving the control signal VCON to the outside.

The power supply unit 230 is a component that generates and supplies the power supply voltage VCC to the amplifier unit 210 and the control unit 220, and generates the power supply voltage VCC using a signal ground SGND as a reference potential, and the sensing circuit unit 200, which includes the amplifier unit 210 and the control unit 220, operates by receiving the power supply voltage VCC using the signal ground SGND as the reference potential.

The sensing circuit unit 200 described above may be configured on the same substrate as the substrate 120 on which the sensing coil 110 is formed, but may also be configured on a separate substrate.

The sensor unit 100 of the present disclosure may be disposed on one side of the power line PL such that a central axis of the sensing coil 110 intersects, preferably perpendicularly intersects, a direction in which current flows through the power line PL.

In particular, in order to reduce the influence of an electric field from the power line PL and reduce sensitivity at a low current, the sensor unit 100 of the present disclosure is disposed such that the lower pattern 112 of the sensing coil 110 is spaced apart from a surface of the power transmission conductor PC by a separation distance SD greater than or equal to a predetermined distance. Here, the separation distance SD may be defined as the shortest distance between the power transmission conductor PC and the sensing coil 110.

Furthermore, the sensor unit 100 of the present disclosure may be configured to be disposed on the grounded power line PL side in the case of a grounded system in order to minimize the influence of the electric field from the power line PL.

Through this configuration, the current sensor of the present disclosure minimizes the influence of noise caused by an electric field from the power line PL to reduce occurrence of errors in current measurement, while obtaining a valid measurement value for a large current to be measured without magnetic saturation.

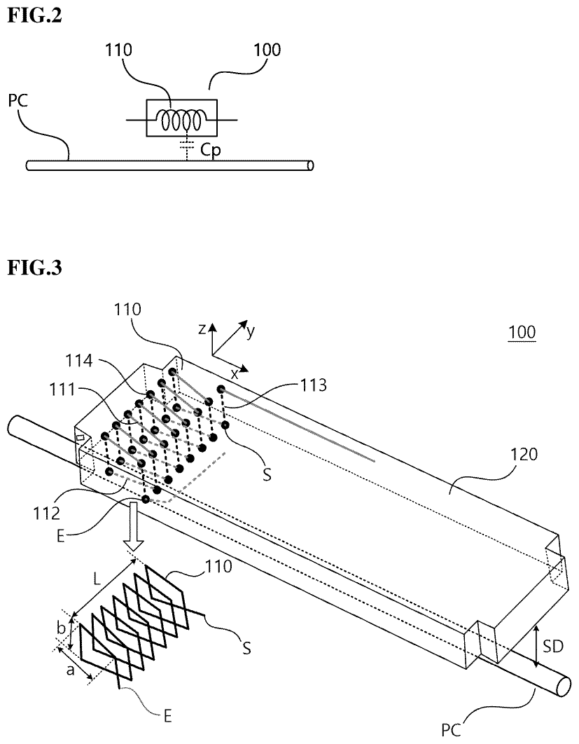

FIG. 2 is a diagram illustrating a case where the current sensor is affected by an electric field from the power line.

Referring to FIG. 2, when the sensor unit 100 is adjacent to the power transmission conductor PC of the power line PL, a parasitic capacitance Cp is formed therebetween, and an electric field generated by the power line PL may affect the sensing coil 110 through the parasitic capacitance Cp. As a result, in addition to the signal corresponding to the current value, the sensing signal Vsen induced in the sensing coil 110 carries a noise signal from the electric field from the power line PL, which may be a factor in reducing the accuracy of the measurement value.

In particular, in order to improve measurement sensitivity so as to measure a low current, when the sensing coil 110 is disposed close to the power transmission conductor PC, the parasitic capacitance Cp increases in inverse proportion to a distance therebetween, thereby increasing the influence of the electric field.

Accordingly, in order to minimize the influence of noise caused by an electric field from the power line PL and reduce the occurrence of errors in current measurement, while allowing a valid measurement value to be obtained for a large current to be measured without magnetic saturation, the current sensor of the present disclosure is disposed such that the lower pattern 112 of the sensing coil 110 is spaced apart from the surface of the power transmission conductor PC by the separation distance SD greater than or equal to a predetermined distance.

In this case, the separation distance SD between the lower pattern 112 of the sensing coil 110 and the surface of the power transmission conductor PC may be set larger as the magnitude of the current to be measured increases.

Generally, as the separation distance SD increases, both the parasitic capacitance Cp and the magnitude of the magnetic field decrease in inverse proportion to the separation distance SD; however, as the separation distance SD increases, curvature of a path formed by the magnetic field decreases while flatness thereof increases.

Therefore, in the current sensor of the present disclosure, when the sensing coil 110 is formed on the planar substrate 120 and a length of the power line PL disposed in a straight line is much greater than a width of the sensing coil 110, as in the sensing unit, even if the separation distance SD increases, magnetic flux and magnetic flux linkage with the sensing coil 110 decrease less than a decrease in the parasitic capacitance Cp. Based on this, the sensor unit 100 is disposed to be spaced apart from the power transmission conductor PC by a separation distance SD equal to or greater than a predetermined distance, thereby further reducing the influence of the electric field while maintaining sensitivity of current measurement to some extent.

FIG. 3 is a perspective view illustrating a state in which the current sensor of the present disclosure is spaced apart from the power line PL.

Referring to FIG. 3, the current sensor of the present disclosure may be configured to include the sensor unit 100 including the substrate 120 having a plurality of conductor layers, and the sensing coil 110 in which a plurality of upper patterns 111 and lower patterns 112 formed on a pair of conductor layers selected from the plurality of conductor layers are formed in a coil shape and output the sensing signal Vsen induced by magnetic coupling with a magnetic flux generated by the current of the power line PL.

The sensor unit 100 is disposed on one side of the power line PL such that a central axis of the sensing coil 110 intersects a current direction of the power line PL, and is disposed such that a lower pattern 112 of the sensing coil 110 is spaced apart from a surface of the power transmission conductor PC by a separation distance SD equal to or greater than a predetermined distance.

For example, when applying the xyz space illustrated in FIG. 3, the power transmission conductor PC may be disposed along the x-axis direction so that current flows in the x-axis direction, and the sensor unit 100 may be disposed above the power transmission conductor PC in the z-axis direction. In this case, the sensing coil 110 may be formed such that the central axis of the sensing coil 110 is in the y-axis direction.

Accordingly, when a current flows through the power transmission conductor PC, a magnetic field is formed parallel to the y-axis, and the sensing signal Vsen is induced in both end portions S and E of the sensing coil 110 by the magnetic flux that links with the sensing coil 110.

Referring to FIG. 3, the sensing coil 110 may be configured to include the plurality of upper patterns 111 formed parallel to each other with a first pattern spacing on the upper layer of a pair of conductor layers, the plurality of lower patterns 112 formed parallel to each other with a second pattern spacing on the lower layer of a pair of conductor layers, and the plurality of vertical conductors 113 formed inside the substrate 120 corresponding to each end portion of the plurality of upper patterns 111 and lower patterns 112, and electrically connecting the upper patterns 111 and lower patterns 112 to form a coil. Here, a connection pad 114 may be formed at a connection point between the vertical conductor 113 and the upper pattern 111, or between the vertical conductor 113 and the lower pattern 112, so that the vertical conductor 113 and the upper pattern 111 or lower pattern 112 may be electrically connected to each other.

In this case, the sensing signal Vsen may be induced in both end portions S and E of the sensing coil 110 by magnetic induction with the magnetic flux generated by the current flowing through the power transmission conductor PC.

The substrate 120 may be a multilayer substrate having two or more conductor layers, and may be formed by combining one or more substrates.

Basically, the upper pattern 111 may be formed with a constant first pattern spacing, and the lower pattern 112 may be formed with a constant second pattern spacing, and the first pattern spacing and the second pattern spacing may be the same spacing.

The vertical conductor 113 is a component that penetrates the upper and lower surfaces of the substrate 120 to electrically connect the upper pattern 111 and the lower pattern 112, and may be implemented in the form of a via hole or other conductor.

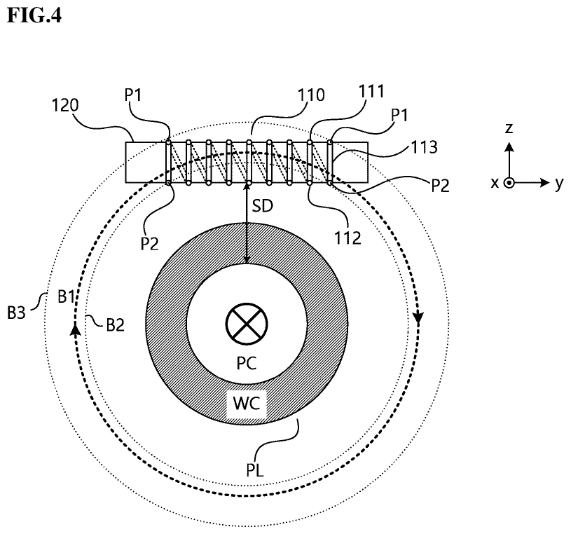

FIG. 4 is a cross-sectional view of the current sensor of the present disclosure projected in an x-axis direction.

Referring to FIG. 4, the sensor unit 100 of the present disclosure is disposed by a predetermined separation distance SD from the surface of the power transmission conductor PC of the power line PL.

In this case, the power line PL may consist only of the power transmission conductor PC, but may be covered with wire coating WC of a certain thickness as illustrated in the drawing.

In order to minimize the parasitic capacitance Cp between the power transmission conductor PC and the sensing coil 110, it may be necessary to maintain a dielectric constant between the power transmission conductor PC and the sensing coil 110 at a low value.

For example, the wire coating WC may be formed of a material having a low dielectric constant or the power line PL may be formed only of the power transmission conductor PC such that an air layer, which is already known as a low-dielectric-constant dielectric, is formed between the power transmission conductor PC and the sensing coil 110. Alternatively, the separation distance SD may be set to a value greater than the thickness of the wire coating WC, or the wire coating WC between the power transmission conductor PC and the sensing coil 110 may be removed. Here, a low dielectric constant may generally refer to a dielectric with a relative dielectric constant of 3 or less.

As illustrated in FIG. 4, when a current flows in a plane along the power transmission conductor PC in the x-axis direction, the magnetic flux is formed clockwise around the power transmission conductor PC.

Among the magnetic fluxes formed around the power transmission conductor PC, referring to the first to third magnetic fluxes B1 to B3 illustrated in FIG. 4, the first magnetic flux B1 links all coil windings constituting the sensing coil 110, and thus it can be seen that the electromotive force induced by the first magnetic flux B1 constitutes a large portion of the sensing signal Vsen.

On the other hand, the second magnetic flux B2 positioned inside the first magnetic flux B1 links most of the coil windings constituting the sensing coil 110 but does not link the coil windings at point P2 of the opposite end portions, thereby inducing a smaller electromotive force than the first magnetic flux B1. In contrast, the third magnetic flux B3 positioned outside the first magnetic flux B1 passes outside point P1 of both end portions of the sensing coil 110, and thus none of the coil windings constituting the sensing coil 110 links with the third magnetic flux B3. Accordingly, the third magnetic flux B3 does not contribute to inducing the sensing signal Vsen.

To improve this, the substrate 120 constituting the sensor unit 100 may be formed as a plate having a curved cross-section extending parallel to the curved magnetic flux lines, or may have an arc shape in cross section. In this case, the cross-sectional shape of the substrate 120 may have different curvatures depending on whether the cross-section of the power transmission conductor PC is circular or plate-shaped like that of a busbar.

However, since manufacturing the substrate 120 of the sensor unit 100 as a curved shape with a certain curvature rather than a flat substrate may increase the difficulty of manufacturing and reduce productivity, it is necessary to devise a method for increasing the magnetic flux linkage between the magnetic flux and the sensing coil 110 while using a flat substrate for the sensor unit 100.

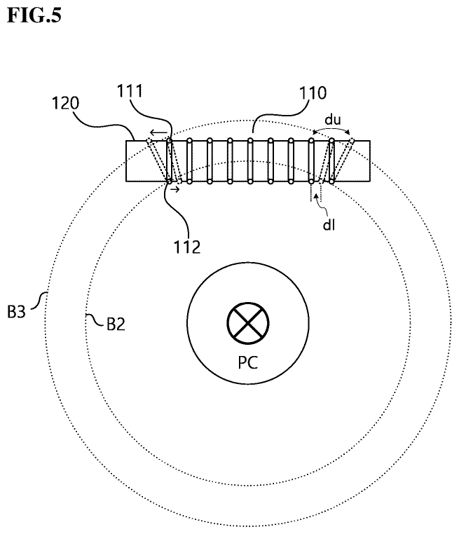

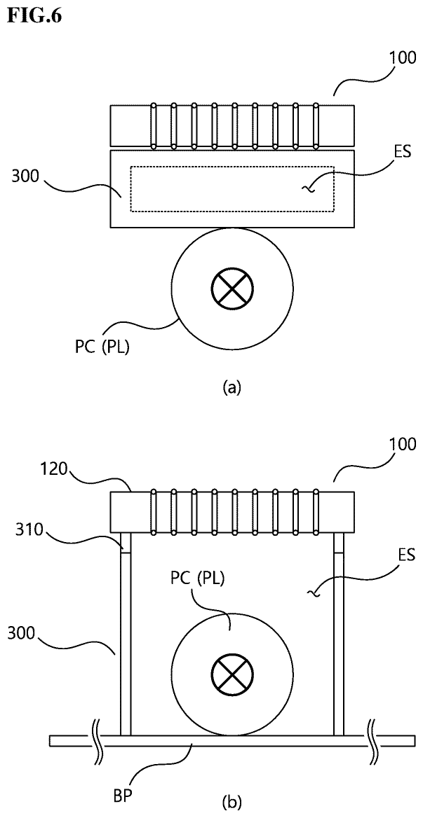

FIG. 5 is a cross-sectional view of a current sensor according to another embodiment of the present disclosure.

Referring to FIG. 5, in the current sensor according to another embodiment of the present disclosure, the upper pattern 111 of the sensing coil 110 may be configured such that the first pattern spacing du of the upper pattern 111 positioned on the outer side in the direction of the central axis of the sensing coil 110 is formed larger than the first pattern spacing du of the upper pattern 111 positioned on the inner side.

Additionally or alternatively, the lower pattern 112 of the sensing coil 110 may be configured such that the second pattern spacing dl of the lower pattern 112 positioned outwardly in the direction of the central axis of the sensing coil 110 is smaller than the second pattern spacing dl of the lower pattern 112 positioned inwardly.

In this way, the lower pattern 112 of the sensing coil 110 may be configured such that the second pattern spacing dl of the lower pattern 112 positioned outwardly is smaller than the second pattern spacing dl of the lower pattern 112 positioned inwardly. As the pattern spacing is adjusted in this manner, the second magnetic flux B2 links with all coil windings, including the coil windings at both end portions of the sensing coil 110, thereby increasing the magnetic flux linkage caused by the second magnetic flux B2. In addition, as the third magnetic flux B3 links with the coil windings at both end portions of the sensing coil 110, the magnetic flux linkage caused by the third magnetic flux B3 also increases. Accordingly, as shown in FIG. 4, a higher sensing signal Vsen may be obtained for the same current than when the first and second pattern spacings du and dl are uniformly configured regardless of whether the coil windings are positioned inwardly or outwardly, thereby improving sensing sensitivity.

In the above description, an example has been described in which only the outermost coil winding among the sensing coil 110 is configured to adjust the first and second pattern spacings (du, dl); however, this does not exclude a configuration in which the pattern spacing between the upper patterns 111 and the lower patterns 112 positioned at inner portions is also adjusted.

However, even in such a case, it is preferable that the first pattern spacing du is uniform such that the inner, middle, and outer first pattern spacings are equal to each other, and that the second pattern spacing dl is uniform such that the outer, middle, and inner second pattern spacings are equal to each other.

FIG. 6 is a diagram illustrating a configuration that maintains a separation distance of the current sensor using a spacer.

Referring to FIG. 6, the current sensor spaced apart from a power line according to the present disclosure may further include a spacer 300 configured to fix the sensor unit 100 to the power line PL or to a base panel BP on which the power line PL is disposed, such that the lower pattern 112 of the sensing coil 110 is spaced apart from the surface of the power transmission conductor PC by a separation distance SD.

In this case, the spacer 300 may be configured such that a low-dielectric-constant dielectric (e.g., an empty space ES) is formed between the lower pattern 112 of the sensing coil 110 and the power transmission conductor PC, thereby reducing parasitic capacitance Cp between the sensing coil 110 and the power transmission conductor PC and allowing the sensing coil 110 to be less affected by an electric field generated by the power line PL.

As illustrated in FIG. 6A, the spacer 300 may be interposed between the power line PL or the power transmission conductor PC and the sensor unit 100, and may preferably include a low-dielectric-constant dielectric. Additionally or alternatively, a hollow empty space ES may be formed inside the spacer 300.

In this way, the spacer 300 interposed between the power line PL or the power transmission conductor PC and the sensor unit 100 may be configured to be directly fixed to the power line PL or the power transmission conductor PC or fixed to the base panel BP on which the power line PL or the power transmission conductor PC is disposed.

Additionally, the spacer 300 may be configured to include a plurality of support legs that support the substrate 120 of the sensor unit 100 by maintaining the separation distance SD between the lower pattern 112 of the sensing coil 110 and the surface of the power transmission conductor PC, as illustrated in FIG. 6B.

By supporting the sensor unit 100 with the plurality of support legs, the empty space ES having a low dielectric constant air layer is formed between the sensing coil 110 and the power transmission conductor PC, which may contribute to reducing the parasitic capacitance Cp along with the separation distance SD.

The spacer 300 of FIG. 6B may be configured to be directly fixed to the power line PL or the power transmission conductor PC, or fixed to a base panel BP on which the power line PL or the power transmission conductor PC is disposed, and may further be provided with a height adjustment unit 310 capable of adjusting the separation distance SD according to current measurement specifications or environment.

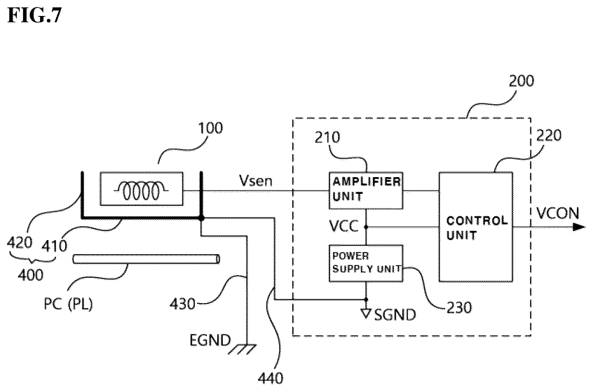

FIG. 7 is a block diagram of the current sensor according to the present disclosure configured by adding a shield unit to block the influence of the electric field of the power line.

Referring to FIG. 7, the current sensor spaced apart from the power line according to the present disclosure may further include a conductive shield unit 400 interposed between the sensor unit 100 and the power line PL to shield the electric field from the power transmission conductor PC toward the sensor unit 100.

As described above, by setting the separation distance SD greater than or equal to a predetermined distance between the sensing coil 110 and the power line PL to reduce the parasitic capacitance Cp between the sensing coil 110 and the power line PL, the influence of the electric field from the power line PL to the sensing coil 110 may be reduced, and the influence of the electric field may be further blocked by interposing the conductive shield unit 400 between the sensor unit 100 and the power line PL.

In this case, the shield unit 400 is interposed between the sensor unit 100 and the power line PL, but may be disposed closer to the sensor unit 100.

Additionally, the shield unit 400 may be configured to include a first shield plate 410 interposed between the sensor unit 100 and the power line PL to block the influence of an electric field generated by the portion of the power line PL facing the sensor unit 100, and a second shield plate 420 coupled to the first shield plate 410 at a predetermined angle so as to surround both end portions of the sensor unit 100 along the length direction of the power line PL, thereby further blocking the influence of an electric field generated by portions of the power line PL other than the portion facing the lower side of the sensor unit 100.

The parasitic capacitance Cp between the sensing coil 110 and the power transmission conductor PC illustrated in FIG. 2 may, when the shield unit 400 is installed, be represented by an equivalent circuit in which a first parasitic capacitance (not illustrated) between the power transmission conductor PC and the shield unit 400, and a second parasitic capacitance (not illustrated) between the shield unit 400 and the sensing coil 110 is connected in series.

In this case, in order to block the effect of the electric field from the power transmission conductor PC on the sensing coil 110, it is preferable to maintain a constant value without fluctuation in the charging voltage at the second parasitic capacitance between the shield unit 400 and the sensing coil 110.

To this end, the shield unit 400 may be grounded to earth ground EGND through the first shield wire 430, or alternatively or additionally, electrically connected to the signal ground SGND of the sensing circuit unit 200 using the second shield wire 440.

When the shield unit 400 is grounded to earth ground EGND, a noise current induced in the shield unit 400 due to fluctuations in the electric field may be bypassed to the earth through the first shield wire 430, such that the earth potential of the shield unit 400 may be stabilized to some extent. However, depending on the magnitude or frequency of the electric field generated by the power line PL, the grounding state of the first shield wire 430, or the length or impedance of the first shield wire 430, the earth potential of the shield unit 400 may fluctuate, thereby allowing electric field noise to be superimposed on the sensing signal Vsen.

Additionally, when the shield unit 400 is connected to the signal ground SGND of the sensing circuit unit 200, the potential of the shield unit 400 may be stably maintained with respect to the signal ground SGND even if noise is induced in the shield unit 400 due to fluctuations in the electric field. However, depending on the magnitude or frequency of the electric field generated by the power line PL, the length or impedance of the second shield wire 440, or the capacitance of the signal ground SGND with respect to the earth, the potential of the shield unit 400 relative to the signal ground SGND may fluctuate, thereby allowing electric field noise to be superimposed on the sensing signal Vsen to some extent.

Accordingly, the shield unit 400 is configured to be grounded to the earth ground EGND by the first shield wire 430 and simultaneously electrically connected to the signal ground SGND of the sensing circuit unit 200 by the second shield wire 440, thereby minimizing the generation of noise to the sensing coil 110 by the electric field from the power line PL.

In this case, the first and second shield wires 430 and 440 may be configured to minimize a common path therebetween, and preferably, the first and second shield wires 430 and 440 may each be independently routed from the shield unit 400 without any shared section.

In addition, the current sensor of the present disclosure may be installed within the enclosure (not illustrated in the drawing) of a power distribution board, a control board, or a distribution board. In this case, the shield unit 400 may be configured such that the first and second shield wires 430 and 440 are electrically connected to the earth ground EGND through the chassis of the enclosure.

In addition, although not illustrated in the drawings, when the power line PL is mounted or fixed on one surface of a conductive base panel BP, the current sensor according to the present disclosure may be installed on the back surface of the base panel BP opposing to the base panel BP so as to be spaced apart from the power transmission conductor PC by a predetermined separation distance SD. In this case, the base panel BP may be configured to function as the shield unit 400 by grounding the base panel BP to earth ground EGND or connecting the base panel BP to the signal ground SGND of the sensing circuit unit 200.

Through the above-described configuration, the current sensor spaced apart from the power line according to the present disclosure may be configured to be spaced apart from the surface of the power line PL or the power transmission conductor PC, and thus may be suitable for measuring large short-circuit currents, ground fault currents, or overcurrents. In addition, since the current sensor is disposed in an open structure while being spaced apart from one side of the power line PL, installation and removal thereof may be facilitated. Furthermore, the influence of noise caused by an electric field generated by the power line PL may be minimized, and the size of the sensor itself may be reduced.

Hereinabove, the present disclosure has been described and illustrated based on preferred embodiments for illustrating the principles of the present disclosure, but the present disclosure is not limited to the configuration and operation as shown and described. It should be understood that the above-mentioned embodiments are exemplary in all aspects but are not limited thereto. It is to be understood that the scope of the present disclosure will be defined by the claims described to be later and all modifications and alternations derived from the claims and their equivalents are included in the scope of the present disclosure.

### DESCRIPTION OF REFERENCE SIGNS

100: Sensor unit
110: Sensing coil
111: Upper pattern
112: Lower pattern
113: Vertical conductor
114: Connection pad
120: Substrate
200: Sensing circuit unit
210: Amplifier unit
220: Control unit
230: Power supply unit
300: Spacer
310: Height adjustment unit
400: Shield unit
410, 420: First and second shield plate
430, 440: First and second shield wire
PL: Power line
PC: Power transmission conductor
WC: Wire coating
du: First pattern spacing
dl: Second pattern spacing
ES: Empty space
BP: Base panel
SGND: Signal ground
EGND: earth ground
Vsen: Sensing signal
VCC: power supply voltage
VCON: Control signal
Cp: Parasitic capacity
SD: Separation distance
B1~B3: First to third magnetic flux

1. A current sensor spaced apart from a power line configured to measure a current of a power transmission conductor provided in the power line that transmits power, the current sensor comprising:
a sensor unit including a substrate including a plurality of conductor layers and a sensing coil outputting a sensing signal induced by magnetic coupling with magnetic flux generated by a current flowing through the power line, the sensing coil including a plurality of upper patterns and lower patterns respectively formed on a pair of conductor layers selected from the plurality of conductor layers and formed in a coil shape,
wherein the sensor unit is disposed on one side of the power line such that a central axis of the sensing coil intersects a current direction of the power line, and the lower pattern of the sensing coil is disposed such that the lower pattern is spaced apart from the surface of the power transmission conductor by a separation distance greater than or equal to a predetermined distance.

2. The current sensor of claim 1, wherein the sensing coil includes:
a plurality of upper patterns formed parallel to each other with a first pattern spacing on an upper layer among the pair of conductor layers;
a plurality of lower patterns formed parallel to each other with a second pattern spacing on a lower layer among the pair of conductor layers; and
a plurality of vertical conductors formed within the substrate corresponding to each end portion of the plurality of upper patterns and lower patterns, respectively, and electrically connecting the upper and lower patterns to form a coil, and
the sensing signal is induced at both end portions of the sensing coil by magnetic induction with the magnetic flux generated by the current flowing through the power transmission conductor.

3. The current sensor of claim 1, wherein the separation distance is set to a larger value as the current of the power transmission conductor to be measured increases.

4. The current sensor of claim 2, wherein the upper pattern of the sensing coil is formed such that the first pattern spacing of the upper pattern positioned outward in a direction of the central axis of the sensing coil is larger than the first pattern spacing of the upper pattern positioned inward.

5. The current sensor of claim 2, wherein the lower pattern of the sensing coil is formed such that the second pattern spacing of the lower pattern positioned outward in the direction of the central axis of the sensing coil is smaller than the second pattern spacing of the lower pattern positioned inward.

6. The current sensor of claim 1, further comprising:
a spacer configured to fix the sensor unit to the power line or a base panel on which the power line is disposed such that the lower pattern of the sensing coil and the surface of the power transmission conductor are disposed while maintaining the separation distance.

7. The current sensor of claim 6, wherein the spacer is configured to form an empty space between the lower pattern of the sensing coil and the surface of the power transmission conductor.

8. The current sensor of claim 1, further comprising:
a sensing circuit unit configured to operate using a signal ground and power supply voltage as a power supply, receive the sensing signal from the sensor unit to detect the current flowing through the power transmission conductor, and output a control signal indicating a detection result of the current or a control command according to the detection result.

9. The current sensor of claim 8, wherein the sensing circuit unit includes:
an amplifier unit configured to amplify the sensing signal;
a control unit configured to receive the amplified sensing signal from the amplifier unit and output a control signal that indicates the current detection result or a control command based on the detection result; and
a power supply unit configured to generate and supply the power supply voltage to the amplifier unit and the control unit.

10. The current sensor of claim 8, further comprising:
a conductive shield unit interposed between the sensor unit and the power line to shield the electric field from the power transmission conductor toward the sensor unit.

11. The current sensor of claim 10, wherein the shield unit is grounded to earth ground.

12. The current sensor of claim 10, wherein the shield unit is electrically connected to a signal ground of the sensing circuit.

13. The current sensor of claim 10, wherein the shield unit is grounded to earth ground by a first shield wire and electrically connected to the signal ground of the sensing circuit unit by a second shield wire.
